(19) United States
(12) Patent Application Publication
(10) Pub. No.: US 2012/0180847 A1
(43) Pub. Date: Jul. 19, 2012

(54) METHOD FOR IMPROVING SOLAR ENERGY CONDENSATION EFFICIENCY IN SOLAR ENERGY CONDENSATION ELECTRIC POWER FACILITY

(75) Inventor: Bruce Wang, Shanghai City (CN)

(73) Assignee: SUNTRIX CO., LTD., SHANGHAI CITY (CN)

(21) Appl. No.: 13/498,914

(22) PCT Filed: Apr. 29, 2010
(86) PCT No.: PCT/CN2010/072314

§ 371 Date: Mar. 29, 2012

(30) Foreign Application Priority Data
Apr. 7, 2010 (CN) 201010141592.0

(51) Int. Cl. H01L 31/052

(52) U.S. Cl. 136/246

(57) ABSTRACT

A method for improving the solar energy condensation efficiency in the solar energy condensation electric power facility is provided. A corresponding twice condensing prism (11) is provided under a condensing lens. A corresponding solar cell is provided under the twice condensing prism. Reflective mirrors (21) are provided around the twice condensing prism. The twice condensing prism is provided in the reflective mirrors. The central axis of the twice condensing prism and the reflective mirrors are coincided. The distance between the normal line of the plane of the light incidence of the twice condensing prism and the reflective mirrors is greater than the distance between the normal line of the plane of the light emergence of the twice condensing prism and the reflective mirrors. The method can uniform the solar energy condensation, and improve the tolerance of the twice optical system.

### BACKGROUND OF THE INVENTION

The present invention relates to the field of power generation by solar energy concentration and more particularly pertains to a method for improving solar energy concentration efficiency in solar energy concentration electric power facility.

High power concentrated photovoltaic power generation technology is a primary and new direction in the field of solar energy power generation. Common solar energy concentration electric power facility generally comprises two main components: a solar energy concentration power generation module and a sun tracking system for supporting the solar energy concentration power generation module. The solar energy concentration power generation module comprises a plurality of concentration lenses 3, a solar cell 4 disposed in the concentration area of each of the concentration lenses 3. A heat dissipating plate 5 is disposed underneath the solar cell 4. The solar cells 4 are connected with each other in series for outputting electric power. As illustrated in FIG. 1, concentration is attained by only using concentration lenses, so some of the sunlight could not be effectively concentrated, and thus the concentration efficiency is not high. Therefore, a secondary concentration prism is conventionally disposed beneath the concentration lens, as illustrated in FIG. 2, to increase the concentration efficiency of the solar energy concentration power generation module.

As illustrated in FIG. 2, a solar energy concentration electric power facility operates mainly by concentrating sunlight on the secondary concentration prism by means of the concentration lens, then the secondary concentration prism uniforms the concentrated sunlight and directs the sunlight to the solar cell. The solar cell then generates direct current by means of photovoltaic effect. As the solar cells are connected with each other in series, the serially connected solar cells increase the voltage and current, thereby output more electric power. As the earth moves around the sun in a periodic ellipsoid pattern, it is essential to ensure that the concentration lens surface and the sunlight maintain perpendicular to each other for attaining the most sunlight. A sun tracking system is used to ensure the perpendicularity between the concentration lens and the sunlight.

At present, with the sensitivity of current sun sensors and the sensitivity of the tracking system, the tracking system fails to ensure the perpendicularity between the concentration lens and the sunlight. As a result, the sunlight concentrated by the concentration lens are deflected to a certain extent, thereby causing some sunlight to deviate from the secondary prism which should be concentrated to the secondary concentration prism, and therefore could not be used for concentration power generation. To overcome the aforementioned problem, some skilled persons in this field have invented a light funnel to replace the secondary concentration prism. The use of light funnel could overcome the problem of the concentration of sunlight, and in recent years extensive research has been carried out in this area in Chinese mainland. However, the use of light funnel raises a new problem which is impossible to avoid, which concerns the uniformity of the sunlight. Uniformity of sunlight is the most important functional benchmark for concentration systems, especially for high power concentration systems. Therefore, light funnels are rarely used in current concentration electric power facilities, especially high power concentration systems.

At present, it is of utmost importance to increase the utilization efficiency of solar energy and to reduce the cost for a unit quantity of electricity so that solar energy, as a green energy, could eventually replace non-renewable energy. The basic way to increase power efficiency for solar energy concentration electric power facility is to increase the solar energy concentration efficiency.

### BRIEF SUMMARY OF THE INVENTION

It is an object of the present invention to provide a method for improving solar energy concentration efficiency in solar energy concentration electric power facility. The method can uniform the solar energy concentration, and improve the tolerance (the allowable range of fluctuation) of the secondary concentration optical system (the secondary concentration prism and reflective mirrors around the secondary concentration prism).

The present invention provides the following technical proposal:

A method for improving solar energy concentration efficiency in solar energy concentration electric power facility, wherein a secondary concentration prism is correspondingly provided under a concentration lens, and a solar cell is correspondingly provided under the secondary concentration prism; reflective mirrors are provided around the secondary concentration prism; the secondary concentration prism is provided within the reflective mirrors; the secondary concentration prism has a central axis which coincides with a central axis of the reflective mirrors; distance between a normal line of a light entrance plane of the secondary concentration prism and the reflective mirrors is greater than distance between a normal line of a light exit plane of the secondary concentration prism and the reflective mirrors.

More particularly, the light entrance plane of the secondary concentration prism has a larger area than the light exit plane, and the secondary concentration prism is center-symmetrical.

More particularly, the light entrance plane and the light exit plane of the secondary concentration prism are both square in shape, and all four sides are trapezium in shape.

More particularly, the reflective mirrors are wide at top and narrow at bottom, which is in shape of a funnel.

More particularly, inner surfaces of the reflective mirrors are coated with films with high reflective index.

More particularly, the films with high reflective index such as Ag—Cu nano films, it is not limited within the Ag—Cu nano films, just an example.

The advantages of the present invention are as follows:

Up till now, the secondary concentration prism has always been used to further concentrate the sunlight from the concentration lens and thereafter direct the sunlight to the solar cells to generate power. To fully reflect the sunlight, the secondary concentration prism has a strict proportional limitation on the length of the light entrance plane, the length of the light exit plane and the height of the prism. This creates a very high demand on the tolerance of the manufacture of secondary concentration prism, thereby causing the costs of the secondary concentration prism to stay high. Using light funnel to replace secondary concentration prism has the problem of uneven concentration. The present invention provides reflective mirrors around the secondary concentration prism to concentrate sunlight, thereby allowing more sunlight from the concentration lens to direct to the solar cell through the secondary concentration prism, thereby improving concentration efficiency. The technical effects of the present invention may be further explained in the following aspects:

(1) Common secondary concentration prism reflects sunlight within the prism under total reflection principle, and finally guides the sunlight through the light exit plane of the secondary concentration prism. However, due to the limitation on the manufacturing tolerance of the concentration lens and the secondary concentration prism and the deviation of the incident angle of the sunlight, some of the sunlight escape from the side surfaces of the secondary concentration prism and therefore concentration efficiency is reduced. After providing reflective mirrors around the secondary concentration prism, the escaped sunlight re-enter the secondary concentration prism by reflecting on via reflective mirrors and finally are guided out through the light exit plane, thereby improving concentration efficiency.

(2) In practical application, the sensitivity and precision of the tracking system could not ensure the sunlight to enter the concentration lens perpendicularly. In concentration power generation facilities using secondary concentration prism, the maximum deviation angle between light source (sunlight) and the concentration lens is allowed to be 1 degree. When the deviation angle exceeds 1 degree, large amount of sunlight escape from the side surface of the secondary concentration prism and the concentration efficiency is greatly reduced. After using the method of the present invention, the deviation degree between the normal line of the light source and the normal line of the secondary concentration prism could reach 2-3 degrees with the concentration efficiency not lower than 90% of that when the sunlight enters perpendicularly, thereby increasing the tolerance of secondary concentration optical systems.

(3) As the present invention provides reflective mirrors around the secondary concentration prism, sunlight that are supposed to escape from the side surface of the secondary concentration prism re-enter the secondary concentration prism after being reflected by the reflective mirrors. As a result, it would not have the light uniformity problem when using light funnel alone, which is that the sunlight are concentrated in the middle area and sparse on the periphery area. The concentration efficiency is thereby improved.

(4) After using the method of the present invention, as reflective mirrors are provided around the secondary concentration prism to reduce the escape of sunlight, the height of the secondary concentration prism could be suitably reduced, and so the focal distance of the concentration lens is also reduced. This would not only significantly reduce the depth of the components of the entire concentration system, but also increase the concentration power and significantly lower costs.

### BRIEF DESCRIPTION OF THE DRAWINGS

FIG. 1 illustrates the operation of a solar energy concentration power generation module without the secondary concentration prism.

FIG. 2 illustrates the operation of a solar energy concentration power generation module with the secondary concentration prism.

FIG. 3 illustrates the secondary concentration prism being a frusto-pyramidal glass body, and each reflective mirror has a convex curved surface at side surface thereof, and that the reflective mirrors are disposed around the secondary concentration prism.

FIG. 4 illustrates the secondary concentration prism being a frusto-pyramidal glass body, and each reflective mirror has a planar surface at side surface thereof, and that the reflective mirrors are disposed around the secondary concentration prism.

FIG. 5 illustrates the secondary concentration prism being a frusto-conical glass body, and the reflective mirror having an annular surface, and that the reflective mirror is disposed around the secondary concentration prism.

FIG. 6 illustrates the secondary concentration prism being a frusto-conical glass body, and the reflective mirror having a convex annular surface, and that the reflective mirror is disposed around the secondary concentration prism.

FIG. 7 illustrates the concentration effects attained by using a light funnel for concentration and by using the method of the present invention for concentration.

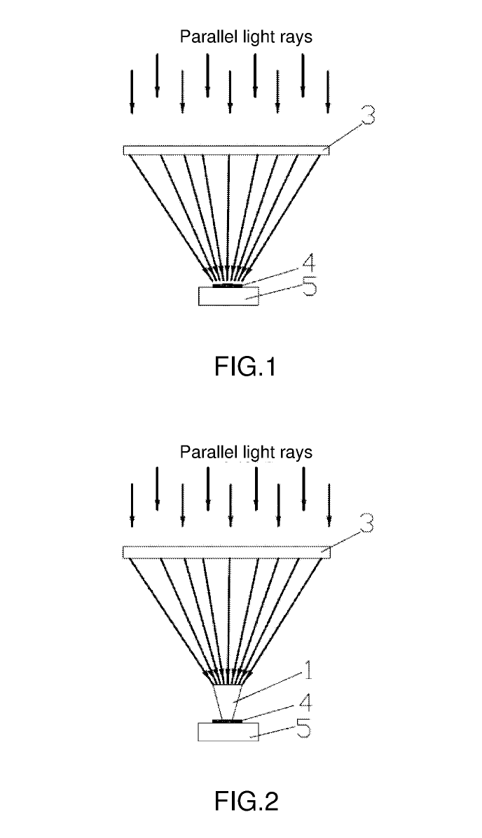

### DETAILED DESCRIPTION OF THE INVENTION

The present invention is further described herein with preferred embodiments.

As illustrated in FIG. 2, a secondary concentration prism 1 is correspondingly provided under a concentration lens 3. A solar cell 4 is correspondingly provided under the secondary concentration prism 1. Reflective mirrors are provided around the secondary concentration prism 1. The secondary concentration prism 1 is provided in the reflective mirrors. The secondary concentration prism 1 has a central axis which coincides with a central axis of the reflective mirrors. The distance between the normal line of the light entrance plane of the secondary concentration prism 1 and the reflective mirrors is greater than the distance between the normal line of the light exit plane of the secondary concentration prism 1 and the reflective mirrors.

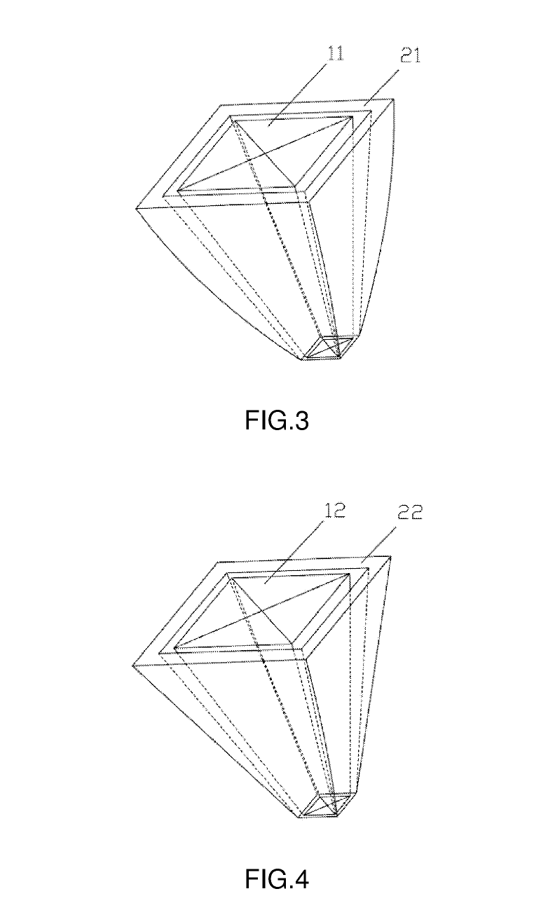

The secondary concentration prism 1 and the corresponding reflective mirrors may be of different shapes. The light entrance plane may be planar or curved. As it is not popular to use a curved light entrance plane, several shapes of the secondary concentration prism and reflective mirrors with planar light entrance plane, which is more common, are shown herein, as illustrated in FIGS. 3-6.

### Embodiment 1

As illustrated in FIG. 3, the secondary concentration prism 11 is an ordinary secondary concentration prism with both top and bottom surfaces being square and center-symmetrical. Four side surfaces of the secondary concentration prism 11 are all trapezoidal. Reflective mirrors 21 formed by reflective planes are provided around the secondary concentration prism 11. Inner surfaces of the reflective planes are coated with Ag—Cu nano films. Outer surfaces of the reflective planes are convex and curved. Bottom edges of the reflective planes and bottom edge of the secondary concentration prism 11 are fixed together by adhesive.

### Embodiment 2

As illustrated in FIG. 4, the secondary concentration prism 12 is an ordinary secondary concentration prism with both top and bottom surfaces being square and center-symmetrical. Four side surfaces of the secondary concentration prism 12 are all trapezoidal. Reflective mirrors 22 formed by reflective planes are provided around the secondary concentration prism 12. Inner surfaces of the reflective planes are coated with Ag—Cu nano films. Outer surfaces of the reflective planes are trapezoidal planar surfaces corresponding to the secondary concentration prism 12. Bottom edges of the reflective planes and bottom edge of the secondary concentration prism 12 are fixed together by adhesive.

### Embodiment 3

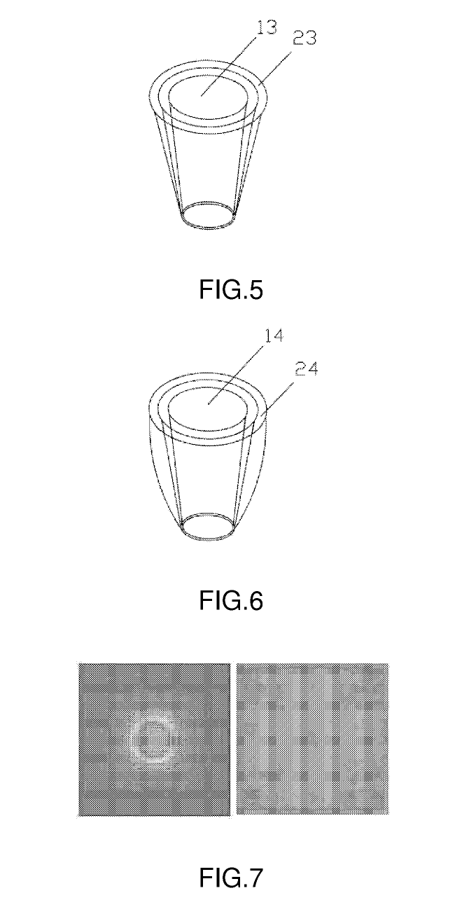

As illustrated in FIG. 5, the secondary concentration prism 13 is a frusto-conical glass body with both top and bottom surfaces being circle. The secondary concentration prism 13 has an annular side surface. A reflective mirror 23 formed by reflective plane is provided around the secondary concentration prism 13. Inner surface of the reflective plane is coated with Ag—Cu nano film. Outer surface of the reflective plane form an annular surface corresponding to the secondary concentration prism 13. Bottom edge of the reflective plane and bottom edge of the secondary concentration prism 13 are fixed together by adhesive.

### Embodiment 4

As illustrated in FIG. 6, the secondary concentration prism 14 is a frusto-conical glass body with both top and bottom surfaces being circle. The secondary concentration prism 14 has an annular side surface. A reflective mirror 24 formed by reflective plane is provided around the secondary concentration prism 14. Inner surface of the reflective plane is coated with Ag—Cu nano film. Outer surface of the reflective plane form a convex annular surface corresponding to the secondary concentration prism 14. Bottom edge of the reflective plane and bottom edge of the secondary concentration prism 14 are fixed together by adhesive.

To facilitate comparison of the present invention and the prior art in respect of its excellence, the following comparison experiments are conducted on Embodiment 1.

### Comparison Experiment 1

Group 1: Use 60 mm frusto-conical glass body as secondary concentration prism;

Group 2: Use 60 mm frusto-conical light funnel reflective lens;

Group 3: Use 60 mm frusto-conical glass body as secondary concentration prism, and reflective mirrors are provided around the frusto-conical glass body; inner surfaces of the reflective mirrors are coated with Ag—Cu nano films; outer surfaces of the reflective planes are convex and curved (i.e. the shapes of the secondary concentration prism and reflective mirrors in Embodiment 1).

The geometric concentration ratio between the concentration lens 3 and the concentration photovoltaic power generation cell is 576. The solar cell 4 takes the form of three III-V solar cells.

Tightly couple the frusto-conical glass body and the solar cell together for each of the Groups either by silica gel or direct contact. Tightly couple the light exit of the frusto-conical light funnel reflective lens to the solar cell together to ensure sunlight at the light exit after concentration to be all guided to the solar cell.

Assemble the solar power concentration power generation module and the tracking system together, so as to real-timely monitor the deflection angle of the direct sunlight from the normal line of the solar power concentration power generation module:

Group 1: When the deflection angle of the direct sunlight exceeds 1 degree from the normal line, the concentration efficiency begins to drop to 90% of that when the deflection angle is 0 degree, and it begins to drop more rapidly.

Group 2: When the deflection angle of the direct sunlight exceeds 0.5 degree from the normal line, the concentration efficiency begins to drop to 90% of that when the deflection angle is 0 degree, and it begins to drop more rapidly.

Group 3: When the deflection angle of the direct sunlight exceeds 3 degrees from the normal line, the concentration efficiency begins to drop to 90% of that when the deflection angle is 0 degree, and it begins to drop more rapidly; and the initial concentration efficiency is also increased by 5%.

In view of the above, the present invention is better in increasing solar power concentration efficiency and reducing precision requirement in solar tracking apparatus in comparison with the prior art.

### Comparison Experiment 2

Group 1: Use 70 mm frusto-conical glass body as secondary concentration prism;

Group 2: Use 70 mm frusto-conical light funnel reflective lens;

Group 3: Use 70 mm frusto-conical glass body as secondary concentration prism, and reflective mirrors are provided around the frusto-conical glass body; inner surfaces of the reflective mirrors are coated with Ag—Cu nano films; outer surfaces of the reflective planes are convex and curved (i.e. the shapes of the secondary concentration prism and reflective mirrors in Embodiment 1).

The geometric concentration ratio between the concentration lens 3 and the solar cell is 576. The solar cell 4 takes the form of three III-V solar cells.

Tightly couple the frusto-conical glass body and the solar cell together for each of the Groups either by silica gel or direct contact. Tightly couple the light exit of the frusto-conical light funnel reflective lens to the solar cell together to ensure sunlight at the light exit after concentration are to be all guided to the solar cell.

Assemble the solar power concentration power generation module and the tracking system together, so as to real-timely monitor the deflection angle of the direct sunlight from the normal line of the solar power concentration power generation module:

Group 1: When the deflection angle of the direct sunlight exceeds 0.7 degree from the normal line, the concentration efficiency begins to drop to 90% of that when the deflection angle is 0 degree, and it begins to drop more rapidly.

Group 2: When the deflection angle of the direct sunlight exceeds 0.3 degree from the normal line, the concentration efficiency begins to drop to 90% of that when the deflection angle is 0 degree, and it begins to drop more rapidly.

Group 3: When the deflection angle of the direct sunlight exceeds 2 degrees from the normal line, the concentration efficiency begins to drop to 90% of that when the deflection angle is 0 degree, and it begins to drop more rapidly; and the initial concentration efficiency is also increased by 5%.

In view of the above, the present invention is better in increasing solar power concentration efficiency and reducing precision requirement in solar tracking apparatus in comparison with the prior art.

A comparison analysis is also conducted on the concentration effects of Group 2 and Group 3 in Comparison experiment 2. The concentration effects are shown in FIG. 7, wherein the concentration effect of Group 2 is shown on the left, and the concentration effect of Group 3 is shown on the right. As illustrated, the concentration light spots of Group 2 which used the light funnel focuses in the middle area of the solar cell, and relatively there are few concentration light spots in the periphery area of the solar cell. In contrast, the concentration light spots of Group 3 which uses the present invention are evenly distributed on the power generation module. In view of the above, the present invention has better concentration uniformity in comparison with the prior art.

The person skilled in the art should understand that the above embodiments are for illustration only for better apprehension of the present invention and should not be considered as limiting the protection scope of the present invention. Any other equivalent variation or decoration according to the spirit of the invention falls within the scope of protection of the present invention.

What is claimed is:

1. A method for improving solar energy concentration efficiency in solar energy concentration electric power facility, wherein a secondary concentration prism is correspondingly provided under a concentration lens, and a solar cell is correspondingly provided under the secondary concentration prism, and characterized in that: reflective mirrors are provided around the secondary concentration prism; the secondary concentration prism is provided within the reflective mirrors; the secondary concentration prism has a central axis which coincides with a central axis of the reflective mirrors; distance between a normal line of a light entrance plane of the secondary concentration prism and the reflective mirrors is greater than distance between a normal line of a light exit plane of the secondary concentration prism and the reflective mirrors.

2. The method for improving solar energy concentration efficiency in solar energy concentration electric power facility as in claim 1, characterized in that: the light entrance plane of the secondary concentration prism has a larger area than the light exit plane, and the secondary concentration prism is center-symmetrical.

3. The method for improving solar energy concentration efficiency in solar energy concentration electric power facility as in claim 1, characterized in that: the light entrance plane and the light exit plane of the secondary concentration prism are both square in shape, and all four sides are trapezium in shape.

4. The method for improving solar energy concentration efficiency in solar energy concentration electric power facility as in claim 2, characterized in that: the reflective mirrors are wide at top and narrow at bottom in shape of a funnel.

5. The method for improving solar energy concentration efficiency in solar energy concentration electric power facility as in any of claims 1 to 4, characterized in that: inner surfaces of the reflective mirrors are coated with films with high reflective index.

6. The method for improving solar energy concentration efficiency in solar energy concentration electric power facility as in claim 5, characterized in that: the films with high reflective index are Ag—Cu nano films.
